(19) United States
(12) Patent Application Publication
(10) Pub. No.: US 2015/0136303 A1
(43) Pub. Date: May 21, 2015

(54) METHOD FOR MANUFACTURING COMPOUND HEAT SINK

(71) Applicant: HUGETEMP ENERGY LTD., Hsinchu County (TW)

(72) Inventors: HUNG-YUAN LI, HSINCHU COUNTY (TW); TSUNG-CHEN CHIANG, HSINCHU COUNTY (TW)

(21) Appl. No.: 14/606,221

(22) Filed: Jan. 27, 2015

Related U.S. Application Data
(63) Continuation-in-part of application No. 14/047,145, filed on Oct. 7, 2013.

(30) Foreign Application Priority Data
May 28, 2013 (TW) 102209887

(51) Int. Cl. H05K 7/20; B05D 3/12; C25D 5/34; B05D 7/00; F28F 21/02; F28F 21/08; B05D 1/36; B05D 3/02

(52) U.S. Cl. CPC H05K 7/20509; B05D 1/36; B05D 3/12; B05D 3/0254; B05D 7/542; F28F 21/02; F28F 21/089; C25D 5/34
USPC 156/60; 427/299; 427/191; 427/202; 427/309; 205/159

(57) ABSTRACT

The present invention provides a method for manufacturing a compound heat sink. Firstly, providing an artificial graphite sheet, and then performing a surface treatment process on the artificial graphite sheet to form a rugged structure on the artificial graphite sheet as a first embedding structure. Finally, forming a metal layer covering the rugged structure, and performing a pressing bonding process to form a second embedding structure corresponding to the first embedding structure to bond the metal layer and the artificial graphite sheet. Namely, the artificial graphite sheet and the metal layer are bonded by the first and second embedding structures for increasing the bonding strength between two heterogeneous materials as well as reducing the interfacial heat resistance. Thereby, the stability of heat dissipation performance can be improved, and a volumetric heat capacity of the compound heat sink from 1.1 to 3.5 J/(cm³·K) is provided.

### REFERENCE TO RELATED APPLICATION

This Application is being filed as a Continuation-in-Part Application of application Ser. No. 14/047,145, filed 7 Oct. 2013, currently pending.

### FIELD OF THE INVENTION

The present invention relates generally to a method for manufacturing a heat sink, and particularly to a method for manufacturing a compound heat sink having excellent thermal conduction property in all of the X-axis, Y-axis, and Z-axis.

### BACKGROUND OF THE INVENTION

Owing to the developments in technologies and the trend of demands in the consumer market, electronic produces have been developing in the direction of high performance, high speed, and compact size. and hence increasing the relative density of electronic devices. Nonetheless, because electronic devices generate a great deal of heat during operation, how to enable electronic products have excellent heat dissipating efficiency given limited device volume for guaranteeing normal operation of the electronic products and thus extending their lifetime has become the primary challenge for modern electronic products.

Because metal sheets have excellent thermal conduction property in all of the X-axis, Y-axis, and Z-axis, metals having high thermal conductivity, such as copper and aluminum, are usually used for manufacturing heat sinks currently for leading out the heat generated during device operations. Nonetheless, compared with copper and aluminum, graphite owns the advantages of lighter weight and higher anisotropic thermal conductivity in X and Y directions. Thereby, nowadays, graphite has been regarded as a superior heat conducting material for solving the heat dissipation problem for modern electronic products.

Nevertheless, graphite sheets are weak and their thermal conductivity is inferior in the Z-axis. These problems limit the application of graphite sheets in heat dissipation. The current solution is to bond a graphite sheet with a metal sheet using a glue layer to form a compound heat dissipating material in hope of reinforcing the thermal conduction performance of the graphite sheet in the Z-axis by the metal sheet. However, under such a bonding method, the existence of the glue layer introduces substantial thermal resistivity between the graphite sheet and the metal sheet, leading to unpromising performance of the compound heat dissipating material in thermal conduction.

Accordingly, the present invention provides a novel method for manufacturing a compound heat sink for solving the problems described above.

### SUMMARY

An objective of the present invention is to provide a method for manufacturing a compound heat sink, which provides that the compound heat sink has superior thermal conductivity in the X-axis, Y-axis, and Z-axis, which bonds a first embedding structure of the first layer and a second embedding structure of the second layer for improving the bonding strength and stability between two heterogeneous materials.

Another objective of the present invention is to provide a method for manufacturing a compound heat sink. When the first layer is an artificial graphite sheet and the second layer is copper or aluminum, the thermal conductivity of the compound heat sink according to the present in the X-axis, Y-axis, and Z-axis can reach above 400 W/m° C., and a volumetric heat capacity of the compound heat sink can be from 1.1 to 3.5 J/(cm³·K).

Still another objective of the present invention is to provide a lightweight and thin compound heat sink.

For achieving the objectives described above, the present invention provides a method for manufacturing a compound heat sink. Firstly, an artificial graphite sheet is provided, and then a surface treatment process is performed on a surface of the artificial graphite sheet. a metal layer is formed thereon. The artificial graphite sheet has a first embedding structure on a surface. The metal layer has a second embedding structure on a surface and corresponding to the first embedding structure. The artificial graphite sheet and the metal layer are bonded firmly by the first and second embedding structures.

The present invention discloses another method for manufacturing a compound heat sink, which comprises a metal layer, an artificial graphite sheet, and a graphite bonding layer composed of graphite powder located between the metal layer and the graphite layer for bonding the metal layer and the graphite layer.

The graphite bonding layer is manufactured by vermicular graphite powder or by mixing vermicular graphite powder and glue.

Moreover, the present invention further discloses a metal oxide layer can be formed on the surface of the metal layer described above.

### BRIEF DESCRIPTION OF THE DRAWINGS

FIG. 1(a) shows a schematic diagram of the compound heat sink according a first embodiment of the present invention;

FIG. 1(b) shows a partially enlarged diagram of FIG. 1(a) according to the present invention;

FIG. 1(c) shows a flowchart for manufacturing the compound heat sink of FIG. 1(a) according an embodiment of the present invention;

FIG. 2 shows a flowchart for manufacturing the compound heat sink of FIG. 1(a) according another embodiment of the present invention;

FIG. 3(a) shows a schematic diagram of the compound heat sink according another embodiment of the present invention;

FIG. 3(b) shows a flowchart for manufacturing the compound heat sink of FIG. 3(a) according an embodiment of the present invention;

FIG. 3(c) shows a schematic diagram of a rugged structure of the compound heat sink according an embodiment of the present invention;

FIG. 4 shows a flowchart for manufacturing the compound heat sink of according an embodiment of the present invention;

FIG. 5(a) shows a schematic diagram of the compound heat sink according another embodiment of the present invention;

FIG. 5(b) shows a flowchart for manufacturing the compound heat sink of FIG. 5(a) according an embodiment of the present invention;

FIG. 6(a) shows a schematic diagram of the compound heat sink according another embodiment of the present invention;

FIG. 6(b) shows a flowchart for manufacturing the compound heat sink of FIG. 6(a) according an embodiment of the present invention;

FIG. 7(a) shows a thermal image of the heat dissipation experiment of the copper layer/glue/artificial graphite sheet compound heat sink according to the prior art to a heat source;

FIG. 7(b) shows a thermal image of the heat dissipation experiment of the artificial graphite sheet without compound copper layer to a heat source;

FIG. 7(c) shows a thermal image of a heat dissipation experiment of the copper layer/artificial graphite sheet compound heat sink according to the present invention to a heat source;

FIG. 8 shows a schematic diagram of the experimental architecture in FIG. 7(a) to FIG. 7(c).

### DETAILED DESCRIPTION

In order to make the structure and characteristics as well as the effectiveness of the present invention to be further understood and recognized, the detailed description of the present invention is provided as follows along with embodiments and accompanying figures.

The spirit of the present invention is to provide a compound heat sink with superior thermal conductivity in the X-axis and Y-axis. The compound heat sink comprises a graphite layer, a metal layer, and a bonding structure located between the graphite layer and the metal layer. The bonding structure can reinforce the bonding strength of the graphite layer and the metal layer.

The compound heat sink can slow down the increment of temperature of electronic product by fitting higher volumetric heat capacity of metal and higher thermal conductivity of graphite. Thereby, heat dissipation effect will be improved and the increment of the temperature will be slowed down. Although the heat capacity of graphite is about 0.71 J/(g·K) and the heat capacity of copper is about 0.385 J/(g·K), a density of copper is many times than a density of graphite. Then, it will cause a larger difference of volumetric heat capacity between graphite and copper. Therefore, a well compound technique of the heat sink will make a well compound heat sink. According to an embodiment, the bonding structure includes a first embedding structure on a surface of the graphite layer and a second embedding structure on a surface and corresponding to the first embedding structure.

The first embedding structure described above can be the material of the graphite layer or formed by surface processing.

In the following, several embodiments are used for describing the present invention. However, the present invention is not limited to the following structure types, materials, or manufacturing methods.

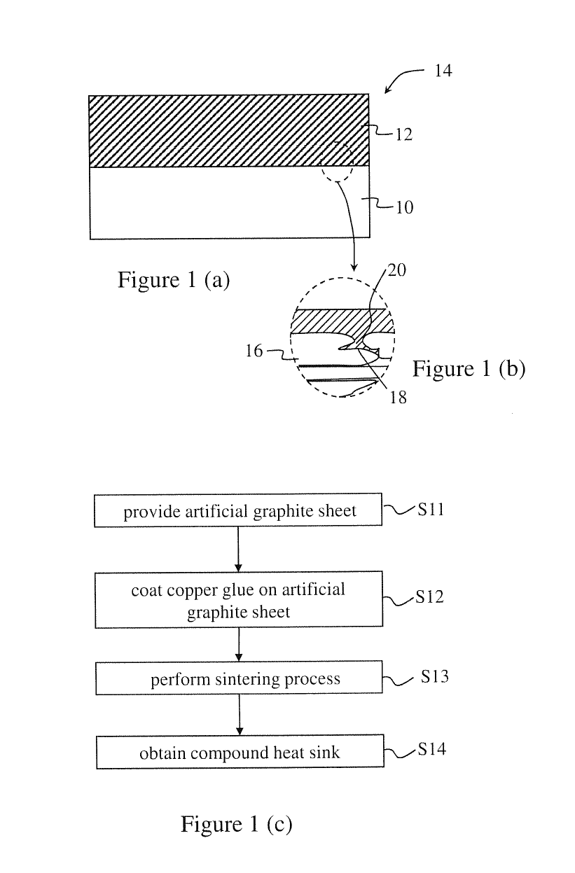

Please refer to FIG. 1(a), FIG. 1(b), and FIG. 1(c), which show a schematic diagram of the compound heat sink according a first embodiment of the present invention, a partially enlarged diagram of FIG. 1(a) according to the present invention, and a flowchart for manufacturing the compound heat sink of FIG. 1(a) according an embodiment of the present invention, respectively.

According to the present embodiment, the first layer is an artificial graphite sheet; the material of the second layer is copper or aluminum. In the following. copper is used as an example.

First, as shown in the step S11, provide an artificial graphite sheet 10. Then, as shown in the step S12, coat copper glue (not shown in the figures) on the artificial graphite sheet 10. Next, as shown in the step S13, sinter the artificial graphite sheet 10 coated with copper glue at approximately 1100□ for removing the glue in the copper glue. Finally, as shown in the step S14, a compound heat sink 14, which is a copper layer 12 on the artificial graphite sheet 10 shown in FIG. 1(a), is given.

According to the present embodiment, because the artificial graphite sheet 10 is composed of multiple stacked and interlaced layers of laminated graphene 16. there are many voids and gaps among graphene. These gaps are then used as the embedding structure 18. Copper glue is formed by mixing copper powders and glue. When coating copper glue on the artificial graphite sheet 10, copper powders will flow into the gaps along with the glue. After the sintering process, the glue will solidify and the copper powder will crystallize and bond during the sintering process, forming the crystal structure embedded in the gaps. The crystal structure is used as the embedding structure 20 corresponding to the embedding structure 18, as shown in FIG. 1(b).

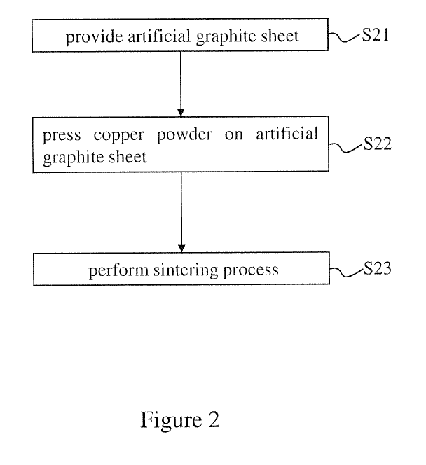

FIG. 2 shows a flowchart for manufacturing the compound heat sink of FIG. 1(a) according another embodiment of the present invention. According to the present embodiment, copper powder is used for replacing the copper glue. First, as shown in the step S21, provide an artificial graphite sheet. Then, as shown in the step S22, spray the copper powder on the artificial graphite sheet for forming a copper powder layer. Next, as shown in the step S23, perform a high-pressure sintering process on the copper powder layer at the pressure of 80 kg/cm² and at the temperature of approximately 1100□. Finally, the compound heat sink as shown in FIG. 1(a) is given.

Because the artificial graphite sheet is composed of multiple stacked and interlaced layers of laminated graphene, there are many gaps on the surface of the artificial graphite sheet. These gaps are then used as the embedding structure. The copper powder will fill into the gaps after the high-pressure sintering process. In addition, the copper powder will crystallize and bond during the sintering process. forming the embedding structure embedded in the gaps.

Besides, graphite powder, such as vermicular graphite powder, can be mixed in the copper powder described above for reinforcing the bonding strength between the copper powder and the artificial graphite sheet.

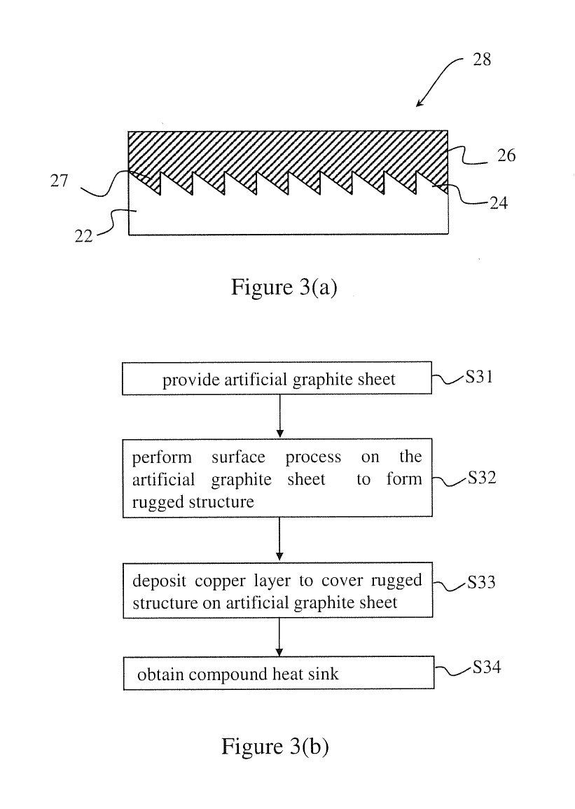

Please refer to FIG. 3(a) and FIG. 3(b), which show a schematic diagram of the compound heat sink according another embodiment of the present invention and a flowchart for manufacturing the compound heat sink, respectively.

According to the present embodiment, the first layer adopts an artificial graphite sheet; the material of the second layer is copper. As shown in the step S31, provide an artificial graphite sheet 22. Then, as shown in the step 932, perform surface process on the artificial graphite sheet 22 for forming a rugged microstructure on the surface as an embedded structure 24. The surface processing methods include pressing the artificial graphite sheet directly using a mold having rugged veins, wet etching, or laser surface processing. As shown in the step S33, form a copper layer 26 on the artificial graphite sheet 22 by using a deposition process, such as copper powder deposition. The copper layer 26 has an embedded structure 27 corresponding to the embedded structure 24. Finally, as shown in the step S34, the compound heat sink 28 ash shown in FIG. 3(a) is given.

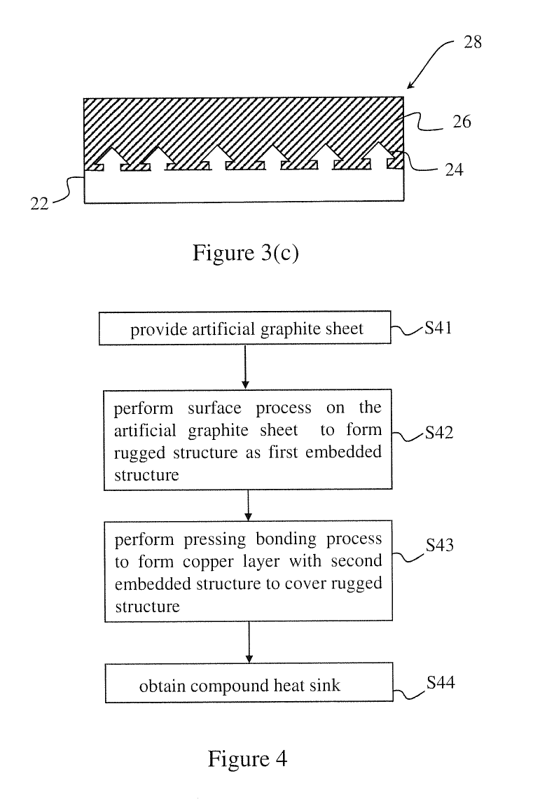

The rugged structure on the surface of the artificial graphite sheet 22 can be rendered as a spear shape, as shown in FIG. 3(c), to be used an embedded structure 24 for enforcing bonding strength between heterogeneous material and the artificial graphite sheet. At the same time, the surface treatment of the artificial graphite sheet can be processed by using O₂ plasma and reactive ion etching. Moreover, the methods for forming the copper layer 26 described above can be a plating process or coating copper glue first and then sintering. For example, a flowchart as shown in FIG. 4, as shown in step S41, provide an artificial graphite sheet 22. Then as shown in step S42, the artificial graphite sheet 22 is processed by a surface treatment to form a rugged structure as a first embedded structure 24 on the artificial graphite sheet 22. Next, as shown in step S43, perform a pressing bonding process to form a copper layer 26 covering the rugged structure on the artificial graphite sheet 22, and the copper layer 26 have a second embedded structure 27 corresponding to the first embedded structure 24 by the pressing bonding process. Thereby, as shown in step S44, obtain the compound heat sink 28 as shown in FIG. 3(a).

The mentioned copper layer can be made of a copper powder layer, so the pressing bonding method can be adopted for forming a copper powder layer first and then performing sintering, in which the copper powder layer can be mixed with graphite powder as well. Alternatively, the copper layer 26 can be formed by disposing a copper foil on the surface of the artificial graphite sheet 26 having the embedding structure 24 and then performing pressing bonding sintering. By using the pressing bonding sintering, the copper foil melts and fills into the gaps in the embedding structure 24, and thus forming the embedding structure matching the embedding structure 24. The related process parameters are described above, and will not be repeated again.

In the following embodiments, the bonding structure is the graphite bonding layer manufactured by vermicular graphite powder.

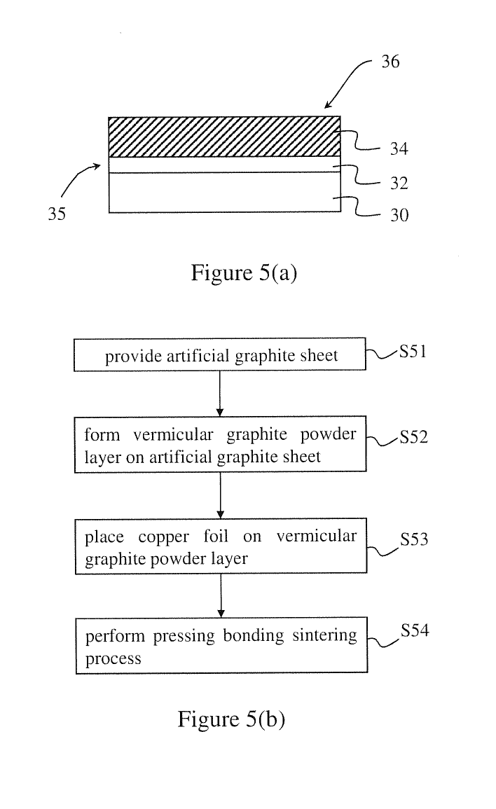

Please refer to FIG. 5(a) and FIG. 5(b), which show a schematic diagram of the compound heat sink according another embodiment of the present invention and a flowchart for manufacturing the compound heat sink, respectively. According to the present embodiment, first, as shown in the step S51, provide a graphite sheet 30. Then, as shown in the step S52, spray a vermicular graphite powder layer 32 on the graphite sheet 30. Next, as shown in the step S53, place a copper foil 34 on the vermicular graphite powder layer 32. Finally, as shown in the step S54, perform a pressing bonding sintering process to give a compound heat sink 36 bonding the copper foil 34 and the graphite sheet 30 using a graphite bonding layer 35 as shown in FIG. 5(a).

According to the present embodiment, the vermicular graphite powder is used for filling the voids or gaps among graphene. In addition, during the pressing bonding sintering process, the copper foil melts, flows into the gaps among vermicular graphite powder, crystallizes, and bonds to form the crystal structure embedded in the gaps.

Besides, the vermicular graphite powder layer can be mixed with glue, as described in the following embodiment.

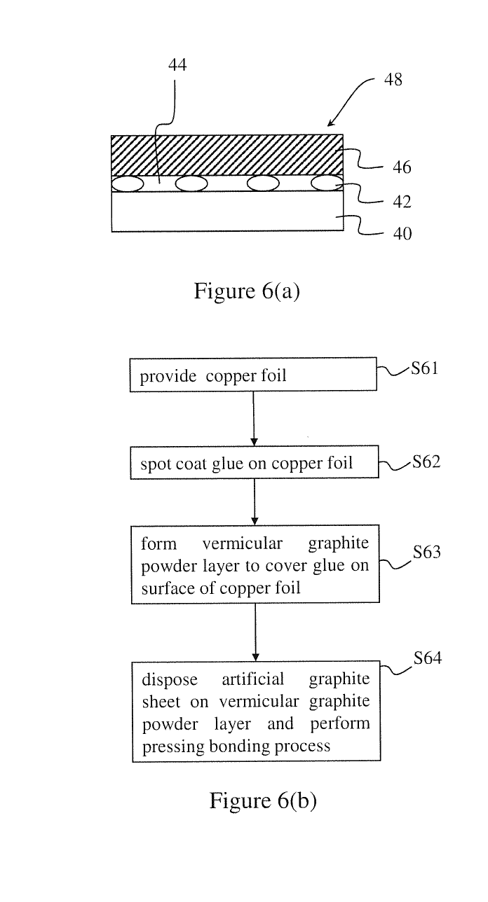

Please refer to FIG. 6(a) and FIG. 6(b), which show a schematic diagram of the compound heat sink according another embodiment of the present invention and a flowchart for manufacturing the compound heat sink. respectively. According to the present embodiment, first, as shown in the step S61, provide a copper foil 40. Then, as shown in the step S62, spot coat glue 42 on the copper foil 40. Next, as shown in the step S63, form a vermicular graphite powder layer 44 covering the glue 42 on the surface of the copper foil. Finally, as shown in the step S64, dispose an artificial graphite sheet 46 on the vermicular graphite powder layer 44 and perform a pressing bonding process to obtain the compound heat sink 48 as shown in FIG. 6(a).

The pressing bonding process according to the present invention includes the thermal pressing bonding process. Thereby, there will be no matching problem of thermal expansion for heterogeneous materials. Not only the stability is enhanced, the interfacial thermal resistivity between two heterogeneous materials can be reduced as well.

Moreover, an oxide layer can be further formed by anode processing on the surface of the metal layer not contacting the graphite layer.

When the artificial graphite sheet and the copper layer (copper foil) are adopted for compounding according to the present invention, the ratio of the thickness of the copper layer to the thickness of the artificial graphite sheet can be between 1:1 and 20:1 for achieving better heat dissipating effect. The ratio of volumetric heat capacity of the metal layer and the artificial graphite sheet is 2:1 to 60:1, and the volumetric heat capacity of the compound heat sink is from 1.1 to 3.5 J/(cm³·K). In addition, by selecting these materials, the thermal conductivity of the compound heat sink according to the present invention in the X-axis, Y-axis, and Z-axis can all reach above 400 W/m□ with superior stability and light weight. Thereby, it can be applied extensively to heat dissipation of many electronic products in the market, such as portable electronic products including mobiles phones and tablet computers.

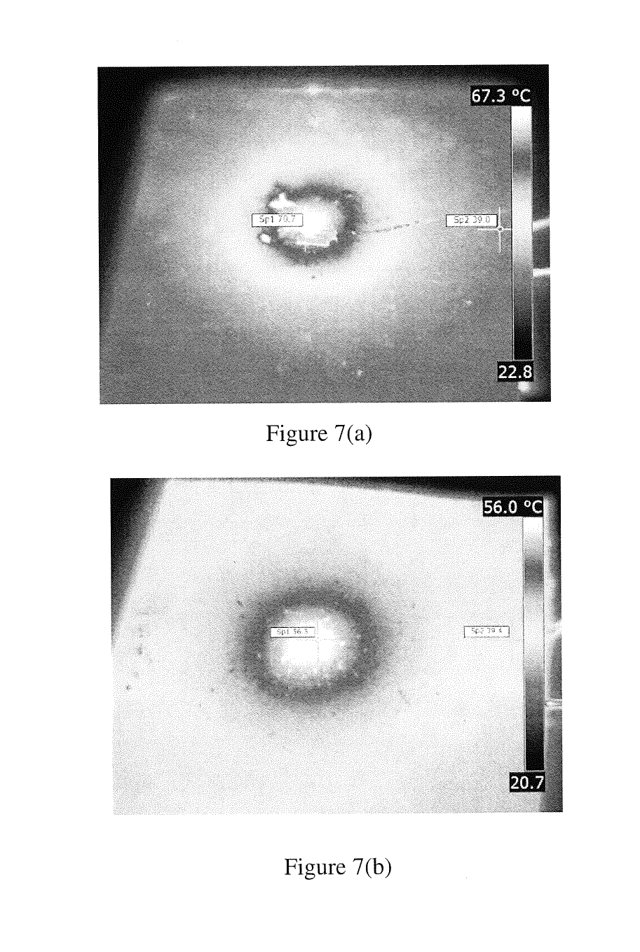

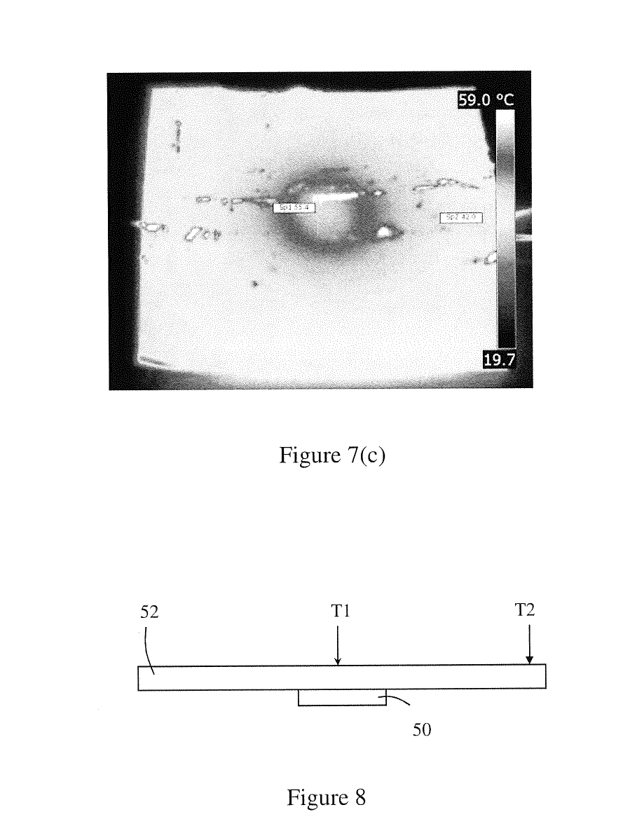

Please refer to FIG. 7(a), FIG. 7(b), and FIG. 7(c), which show thermal images of the heat dissipation experiment of the copper layer/glue/artificial graphite sheet compound heat sink according to the prior art, the artificial graphite sheet without compound copper layer, and the copper layer/artificial graphite sheet compound heat sink according to the present invention to a heat source, respectively. The diagram of the experimental architecture is shown in FIG. 8. A 4-Watt, 20×20 mm² LED die is used as the heat source 50 disposed at the center of the heat sink 52. The area of the heat sink 52 is 100×100 mm². The temperature sensing point is selected to he the central point T1 and the edge point T2; the spacing between T1 and T2 is 50 mm.

As shown in the figure, the temperature at the center of the copper layer/glue/artificial graphite sheet compound heat sink according to the prior art reaches 70.7□for the artificial graphite sheet without compound copper layer, the temperature at the center is 56.3□; and for the copper layer/artificial graphite sheet compound heat sink according to the present invention, the temperature at center is 55.4□. Thereby, the compound heat sink according to the present invention has superior thermal conducting effect. The existence of glue contrarily makes the thermal conducting effect of the artificial graphite sheet inferior.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

1. A method for manufacturing a compound heat sink, comprises the steps of:
Step 1: providing an artificial graphite sheet;
Step 2: performing a surface treatment process on a surface of said artificial graphite sheet to form a rugged structure as a first embedded structure thereon; and
Step 3: forming a metal layer covering said rugged structure on said artificial graphite sheet, and performing a pressing bonding process for forming a second embedded structure which is corresponding to said first embedded structure on metal layer to bond said metal layer and said artificial graphite sheet.

2. The method as claimed in claim 1, wherein when said metal layer is copper, the ratio of the thickness of said metal layer to the thickness of said artificial graphite sheet is 1:1 to 20:1.

3. The method as claimed in claim 1, before said step 3, further comprising a step of:
forming a vermicular graphite powder layer on said artificial graphite sheet.

4. The method as claimed in claim 3, wherein said metal layer is formed of metal powders covered on said vermicular graphite powder layer.

5. The method as claimed in claim 1, wherein the surface treatment process is performed by using a mold having rugged veins to press and print said graphite layer directly, or performed by micro-etching.

6. The method as claimed in claim 1, further comprising a step of:
performing an anodic process to form an oxide layer on a surface which is opposite to the surface bonding said artificial graphite sheet of said metal layer.

7. The method as claimed in claim 1, wherein said metal layer includes copper or aluminum.

8. The method as claimed in claim 1, wherein said pressing bonding process is a thermal pressure sintering process.

9. The method as claimed in claim 1, wherein after bonding said metal layer and said artificial graphite sheet, the coefficients of thermal conductivity of said metal layer and said artificial graphite sheet are all above 400W/m° C. at the X-axis and Y-axis.

10. The method as claimed in claim 1, wherein when said metal layer is selected from copper, the ratio of volumetric heat capacity of said metal layer and said artificial graphite sheet is 2:1 to 60:1.

11. The method as claimed in claim 1, wherein volumetric heat capacity of said compound heat sink is from 1.1 to 3.5 J/(cm³·K).

12. A method for manufacturing a compound heat sink, comprises the steps of:
providing a metal layer;
coating a glue on said metal layer;
forming a vermicular graphite powder layer on said metal layer, and said vermicular graphite powder layer covering said glue;
disposing an artificial graphite sheet on said metal layer, and said artificial graphite sheet covering said vermicular graphite powder layer at the same time; and
performing a pressing bonding process for bonding said metal layer and said artificial graphite sheet.

13. The method as claimed in claim 12, wherein when the metal layer is copper, the ratio of the thickness of said metal layer to the thickness of said artificial graphite sheet is 1:1 to 20:1.

14. The method as claimed in claim 12, further comprising a step of:
performing an anodic process to form an oxide layer on a surface which is opposite to the surface bonding said artificial graphite sheet of said metal layer.

15. The method as claimed in claim 12, wherein said pressing bonding process is a thermal pressure sintering process.

16. The method as claimed in claim 12, wherein after bonding said metal layer and said artificial graphite sheet, the coefficients of thermal conductivity of said metal layer and said artificial graphite sheet are all above 400W/m° C. at the X-axis and Y-axis.

17. The method as claimed in claim 12, wherein said metal layer includes copper or aluminum.

18. The method as claimed in claim 12, wherein after bonding said metal layer and said vermicular graphite powder layer, the distributed of said glue is discontinuous.

19. The method as claimed in claim 12, wherein when said metal layer is selected from copper, the ratio of volumetric heat capacity of said metal layer and said artificial graphite sheet is 2:1 to 60:1.

20. The method as claimed in claim 12, wherein volumetric heat capacity of said compound heat sink is from 1.1 to 3.5 J/(cm³·K).
